(19) United States
(12) Patent Application Publication
(10) Pub. No.: US 2016/0002789 A1
(43) Pub. Date: Jan. 7, 2016

(54) SUBSTRATE PROCESSING APPARATUS, METHOD FOR MANUFACTURING SEMICONDUCTOR DEVICE, AND RECORDING MEDIUM

(71) Applicant: HITACHI KOKUSAI ELECTRIC INC., Tokyo (JP)

(72) Inventors: Tadashi KONTANI, Toyama-shi (JP); Hideto TATENO, Toyama-shi (JP); Atsushi UMEKAWA, Toyama-shi (JP)

(73) Assignee: HITACHI KOKUSAI ELECTRIC INC., Tokyo (JP)

(21) Appl. No.: 14/856,312

(22) Filed: Sep. 16, 2015

Related U.S. Application Data
(63) Continuation of application No. PCT/JP2014/058301, filed on Mar. 25, 2014.

(51) Int. Cl. C23C 16/52; C23C 16/455; H01L 21/02; C23C 16/44

(52) U.S. Cl. CPC C23C 16/52; C23C 16/4412; C23C 16/455; H01L 21/02271

(57) ABSTRACT

A substrate processing apparatus includes a processing chamber housing a substrate, a vaporizer which vaporizes processing liquid and supply processing gas into the processing chamber, a reserve tank storing the processing liquid, a line switching unit connected to the reserve tank, a tank supply pipe connected to the line switching unit and supplies the processing liquid to the reserve tank, an exhausting unit connected to the line switching unit and exhausts the processing liquid in the reserve tank, and a controlling unit which controls the line switching unit to exhaust the processing liquid for exhausting the processing liquid from the reserve tank to the exhausting unit and exhaust the processing liquid in the pipe for supplying the processing liquid from the tank supply pipe to the exhausting unit before and/or after supplying the processing liquid from the processing liquid supplying pipe to the reserve tank.

### TECHNICAL FIELD

The present invention relates to a substrate processing apparatus for processing a substrate, a method of manufacturing a semiconductor device, and a recording medium.

### BACKGROUND ART

According to the miniaturization of a large scale integrated circuit (LSI), technical difficulty regarding processing technique for controlling leakage current interference between transistor elements has been increased. An interelement isolation of the LSI is performed by using a method in which a gap such as a groove or a hole is formed between elements to be isolated in silicon (Si) which is a substrate and an insulator is deposited in the gap. An oxide film is often used as the insulator, and, for example, a silicone oxide film is used. The silicone oxide film is formed by oxidation of the Si substrate, a chemical vapor deposition (CVD), and a spin on dielectric (SOD) method.

According to the recent miniaturization, an embedding method according to the CVD method relative to an embedding a fine structure, more specifically, an embedding of an oxide to a gap structure which is deep in the vertical direction and narrow in the horizontal direction, is reaching the technical limit. In accordance with this background, employments of an embedding method using an oxide having fluidity, that is, the SOD have been increased. In the SOD, a coating insulating material which is referred to as a spin on glass (SOG) and includes an inorganic or organic components is used. This material has been employed in a step of manufacturing the LSI before the appearance of a CVD oxide film. However, since the processing technique is used for a working dimension of about 0.35 μm to 1 μm that is not fine, a modification method after coating has been performed by performing heat processing at about 400° C. in nitrogen atmosphere.

On the other hand, a request for reducing a thermal load of a transistor has been increased. Reasons to reduce the thermal load include to prevent an excessive diffusion of impurities, such as boron, arsenic, and phosphorus implanted for an operation of an transistor, to prevent cohesion of metal silicide for an electrode, to prevent performance variations of a work function metal material for a gate, to secure a repetition lifetime of a write and read of a memory element, and the like.

### SUMMARY OF INVENTION

### Technical Problem

However, the minimum working dimension of the semiconductor device represented by the LSI, a dynamic random access memory (DRAM), and a flash memory in recent years has been smaller than the width of 50 nm. To miniaturize the device while maintaining the quality, to improve of a throughput of manufacturing the device, and to lower the processing temperature have been difficult.

A purpose of the present invention is to improve a quality of manufacturing a semiconductor device and to provide a substrate processing apparatus, a method of manufacturing a semiconductor device, and a recording medium which can improve a throughput of manufacturing the device.

### Solution to Problem

According to one aspect, there is provided a substrate processing apparatus includes a processing chamber for housing a substrate, a vaporizer for vaporizing processing liquid and supplying processing gas into the processing chamber, a reserve tank for storing the processing liquid, a flow rate control unit for controlling a flow rate of the processing liquid from the reserve tank to the vaporizer, a line switching unit connected to the reserve tank, a tank supply pipe for being connected to the line switching unit and supplying the processing liquid to the reserve tank, an exhausting unit for being connected to the line switching unit and exhausting the processing liquid in the reserve tank, and a controlling unit for controlling the line switching unit to perform a step of exhausting the processing liquid for exhausting the processing liquid from the reserve tank to the exhausting unit and a step of exhausting the processing liquid in the pipe for exhausting the processing liquid from the tank supply pipe to the exhausting unit before and/or after a processing liquid replenishing step of supplying the processing liquid from the tank supply pipe to the reserve tank.

According to another aspect, there is provided a method of manufacturing a semiconductor device includes (a) housing a substrate in a processing chamber, (b) storing processing liquid in a reserve tank, (c) supplying the processing liquid from the reserve tank to a vaporizer, (d) vaporizing the processing liquid and supplying processing gas into the processing chamber, (e) supplying the processing liquid from a tank supply pipe to the reserve tank, and (f) performing a step of exhausting the processing liquid in the reserve tank from an exhausting unit and a step of exhausting the processing liquid from the tank supply pipe to the exhausting unit before and/or after the act of (e).

According to still another aspect, there is provided a non-transitory computer-readable recording medium in which a program has been recorded. The program makes a computer perform a procedure of housing a substrate in a processing chamber, a procedure of storing processing liquid in a reserve tank, a procedure of supplying the processing liquid from the reserve tank to the vaporizer, a procedure of vaporizing the processing liquid and supplying processing gas in the processing chamber, a procedure of supplying the processing liquid from the tank supply pipe to the reserve tank, and a procedure of performing a procedure of exhausting the processing liquid in the reserve tank from an exhausting unit and a procedure of exhausting the processing liquid from the tank supply pipe to the exhausting unit before and/or after the procedure of supplying the processing liquid from the tank supply pipe to the reserve tank.

### Advantageous Effects of Invention

According to a substrate processing apparatus, a method of manufacturing a semiconductor device, and a recording medium according to the present invention, a quality of manufacturing the semiconductor device can be improved, and a throughput of manufacturing the device can be improved.

### BRIEF DESCRIPTION OF DRAWINGS

FIG. 1 is a schematic block diagram of a substrate processing apparatus according to an embodiment.

FIG. 2 is a vertical section schematic diagram of the substrate processing apparatus according to the embodiment.

FIG. 3 is a schematic block diagram of a controller of the substrate processing apparatus preferably used in the embodiment.

FIG. 4 is a flowchart of a substrate processing step according to the embodiment.

FIG. 5 is a diagram of a line switching unit of the substrate processing apparatus and a processing liquid replenishing step of a reserve tank according to the embodiment.

FIG. 6 is a diagram of a structure of a line switching unit of the substrate processing apparatus during a step of exhausting the processing liquid according to the embodiment.

FIG. 7 is a diagram of a structure of a line switching unit of the substrate processing apparatus during an exhausting step in a processing liquid supplying pipe according to the embodiment.

FIG. 8 is a schematic block diagram of a vaporizer according to other embodiment.

### DESCRIPTION OF EMBODIMENTS

### First Embodiment

A first embodiment will be described below.

(1) Structure of Substrate Processing Apparatus

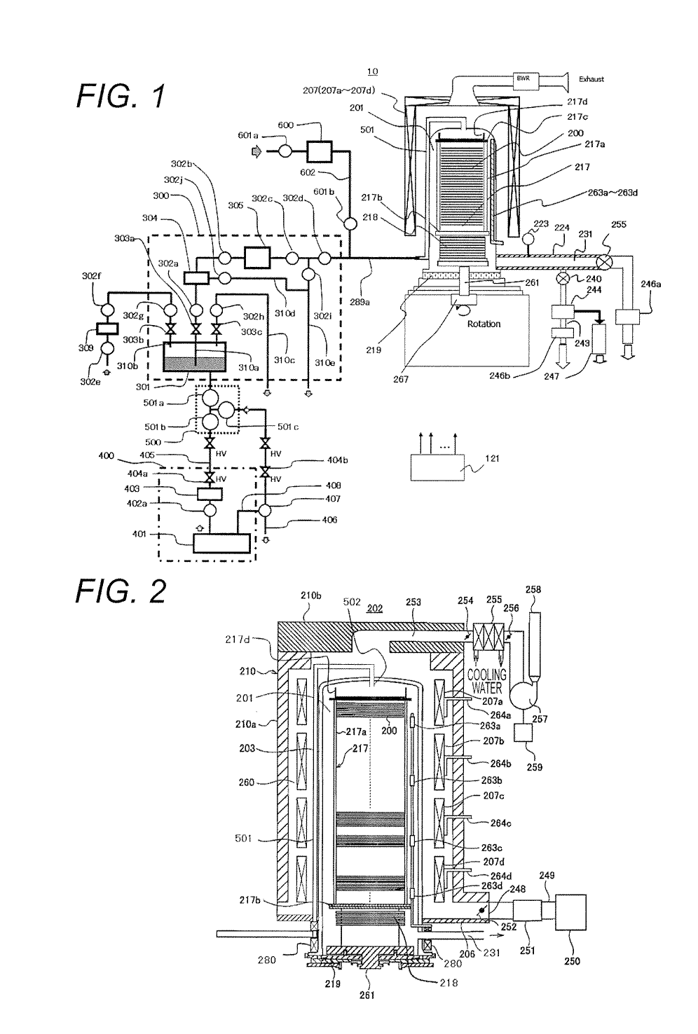

A structure of a substrate processing apparatus according to the present embodiment will be described with reference to mainly FIGS. 1 and 2. FIG. 1 is a schematic block diagram of the substrate processing apparatus according to the present embodiment, and a vertical section of a processing furnace 202 is illustrated. FIG. 2 is a vertical section schematic diagram of the processing furnace 202 included in the substrate processing apparatus according to the present embodiment.

(Reaction Tube)

The processing furnace 202 includes a reaction tube 203 as illustrated in FIG. 1. The reaction tube 203 is formed of a heat resistant material such as quartz (SiO₂) or silicon carbide (SiC) and is formed in a cylindrical shape of which an upper and lower ends are opened. A processing chamber 201 is formed in a cylindrical hollow part in the reaction tube 203, and wafers 200 as a substrate can be stored in a state where the plurality of wafers 200 in a horizontal attitude is aligned in multistage in the vertical direction by a boat 217.

On the bottom of the reaction tube 203, a seal cap 219 is provided as an opening lid which can seal (close) a lower end opening (opening) of the reaction tube 203 to be airtight. The seal cap 219 is configured to be abutted on the lower end of the reaction tube 203 from the lower side in the vertical direction. The seal cap 219 is formed in a disk shape. The substrate processing chamber 201 which is a processing space of the substrate includes the reaction tube 203 and the seal cap 219.

(Substrate holding unit)

The boat 217 as a substrate holding unit can hold the plurality of wafers 200 in multistage. The boat 217 has a plurality of supporting columns 217a for holding the plurality of wafers 200. For example, three supporting columns 217a are included. The plurality of supporting columns 217a is provided between a bottom plate 217b and a top plate 217c. The plurality of wafers 200 is held in multistage in a tube axis direction in a state where the wafers 200 are positioned in the horizontal attitude relative to the supporting columns 217a and are aligned as having the centers overlapped with each other. The top plate 217c is formed to be larger than the maximum outer diameter of the wafer 200 to be held by the boat 217.

As materials of the supporting column 217a, the bottom plate 217b, and the top plate 217c, a non-metallic material with excellent heat conductivity are used, such as silicon oxide (SiO₂), silicon carbide (SiC), aluminum oxide (AlO), aluminum nitride (AlN), silicon nitride (SiN), and zirconium oxide (ZrO). Especially, it is preferable to use a non-metallic material which has heat conductivity of equal to or more than 10 W/mK. When the heat conductivity does not cause a problem, they may be formed by using quartz (SiO) and the like. Also, metal contamination in the wafer 200 does not cause a problem, the supporting column 217a and the top plate 217c may be formed by using a metallic material such as stainless (SUS). When metal is used as the materials of the supporting column 217a and the top plate 217c, a film such as a ceramic and Teflon (registered trademark) may be formed on the metal.

A heat insulator 218 configured of a heat resistant material such as quartz and silicon carbide is provided under the boat 217 so that the heat from a first heating unit 207 is hard to be conducted to the side of the seal cap 219. The heat insulator 218 functions as a heat insulation member and a holding body for holding the boat 217. The heat insulator 218 is not limited to the one in which a plurality of disk-shaped heat insulation plates positioned in the horizontal attitude is provided in multistage as illustrated in FIGS. 1 and 2. For example, the heat insulator 218 may be a quartz cap formed in a cylindrical shape. Also, the heat insulator 218 may be considered as one of the members of the boat 217.

(Ascending/Descending Unit)

A boat elevator as an ascending/descending unit for transferring the boat 217 to/from the reaction tube 203 by ascending/descending the boat 217 is provided under the reaction container 203. In the boat elevator, the seal cap 219 is provided which seals the opening when the boat 217 is ascended by the boat elevator.

On a side of the seal cap 219 opposite to the processing chamber 201, a boat rotating mechanism 267 for rotating the boat 217 is provided. A rotation shaft 261 of the boat rotating mechanism 267 is connected to the boat 217 as passing through the seal cap 219 so as to rotate the wafer 200 by rotating the boat 217.

(First Heating Unit)

A first heating unit 207 for heating the wafer 200 in the reaction tube 203 is provided outside the reaction tube 203 and is concentrically arranged so as to surround the side wall surface of the reaction tube 203. The first heating unit 207 is provided by being supported by a heater base 206. As illustrated in FIG. 2, the first heating unit 207 includes a first to fourth heater units 207a to 207d. The first to fourth heater units 207a to 207d are arranged along the lamination direction of the wafers 200 in the reaction tube 203.

In the reaction tube 203, each of the first to fourth temperature sensors 263a to 263d such as the thermocouple is provided between the reaction tube 203 and the boat 217 as a temperature detector for detecting the temperature of the wafer 200 or an ambient temperature for each first to fourth heater units 207a to 207d. Also, the first to fourth temperature sensors 263a to 263d may be provided to detect the temperature of the wafer 200 positioned at the center of the plurality of wafers 200 respectively heated by the first to fourth heater units 207a to 207d.

The first heating unit 207 and the first to fourth temperature sensors 263a to 263d are electrically connected to a controller 121 described later. The controller 121 controls power supply to each of the first to fourth heater units 207a to 207d at a predetermined timing and individually sets and adjusts the temperature of each first to fourth heater units 207a to 207d based on temperature information respectively detected by the first to fourth temperature sensors 263a to 263d so that the temperature of the wafer 200 in the reaction tube 203 becomes a predetermined temperature.

(Gas Supplying Unit)

As illustrated in FIG. 1, a processing liquid supplying nozzle 501 is provided between the reaction tube 203 and the first heating unit 207. For example, the processing liquid supplying nozzle 501 is formed of quartz with low heat conductivity. The processing liquid supplying nozzle 501 may have a double tube structure. The processing liquid supplying nozzle 501 is arranged along a side part of an exterior wall of the reaction tube 203. A top end part (downstream end) of the processing liquid supplying nozzle 501 is provided at the top (upper end opening) of the reaction tube 203 to be airtight. A supply hole 502 is provided at the top end of the processing liquid supplying nozzle 501 positioned above the upper end opening of the reaction tube 203. The supply hole 502 is configured to supply the processing liquid, which is supplied to the reaction tube 203, to the vaporizer 217d provided on the upper side of the boat 217 housed in the reaction tube 203. In the example described later, the supply hole 502 is configured to drip the processing liquid to the vaporizer 217d. However, the supply hole 502 may be configured to inject the processing liquid as necessary. A gas supplying unit mainly includes the vaporizer 217d, the processing liquid supplying nozzle 501, and the supply hole 502.

An upstream end of the processing liquid supplying nozzle 501 is connected to the downstream end of a processing liquid supplying pipe 289a which supplies the processing liquid. A liquid flow rate control unit 300 and a processing liquid supplying unit 400 are provided in the processing liquid supplying pipe 289a in an order from the upstream side.

(Liquid Flow Rate Control Unit)

The liquid flow rate control unit 300 has a reserve tank 301, a liquid pipe 310a, an automatic valve 302a, a hand valve 303a, a filter 304, an automatic valve 302b, a liquid flow rate controller (LMFC) 305 as a flow rate control unit, and valves 302c and 302d provided therein in an order from the upstream side. The upstream end of the liquid pipe 310a is provided under a liquid surface in the reserve tank 301. Also, the reserve tank 301 is connected to a pumped gas supplying unit, a gas exhausting unit, and a processing liquid exhausting unit. A capacity of the reserve tank 301 is from one to five liters, for example, two liters. Preferably, the reserve tank 301 has the capacity in which a substrate processing step described later can be performed more than once in a row.

The pumped gas supplying unit has a gas pipe 310b, automatic valves 302e, 302f, and 302g, a gas flow rate controller (mass flow controller) 309, and a hand valve 303b provided therein. The pumped gas supplying unit mainly includes the gas pipe 310b, the automatic valve 302g, and the MFC 309. Other components may be included in the pumped gas supplying unit. The processing liquid is pumped from the reserve tank 301 to the filter 304 by supplying the pumped gas such as nitrogen gas (N₂) from the pumped gas supplying unit to the reserve tank 301.

The gas exhausting unit has a gas pipe 310c, a hand valve 303c, and an automatic valve 302h provided therein. The gas exhausting unit includes at least the gas pipe 310c and the automatic valve 302h. The hand valve 303c may be included as necessary.

A drain pipe 310e and an automatic valve 302i are provided between the automatic valves 302c and 302d. Also, a gas pipe 310d connected to the drain pipe 310e and an automatic valve 302j are provided in the filter 304. The filter 304 takes out the gas included in the processing liquid supplied from the reserve tank 301 and sends the liquid to the LMFC 305. The gas included in the processing liquid flows into the drain pipe 310e. The LMFC 305 controls the flow rate of the processing liquid supplied via the filter 304.

(Processing Liquid Supplying Unit)

The processing liquid supplying unit 400 supplies the processing liquid to the reserve tank 301. The processing liquid supplying unit 400 includes a processing liquid supply source 401, an automatic valve 402a, a pump 403, a hand valve 404a, a tank supply pipe 405, and an automatic valve 404b provided therein. The processing liquid supplying unit 400 includes at least the tank supply pipe 405 and the automatic valve 402a. In addition, the processing liquid supplying unit 400 may include an exhausting pipe 406 as an exhausting unit described later. Also, the processing liquid supply source 401 and the pump 403 may be included. However, they may be provided as a system of a semiconductor device manufacturing factory where the substrate processing apparatus is provided. The pump 403 is provided so as to supply the processing liquid from the processing liquid supply source 401 to the reserve tank 301 via a line switching unit described later. The processing liquid supplying unit 400 may be provided in the gas supplying unit. Also, the processing liquid supplying unit 400 may be provided as a system of the semiconductor device manufacturing factory where the substrate processing apparatus is provided without being provided in the substrate processing apparatus.

(Exhausting Unit)

A line switching unit 500 described later is connected to the exhausting pipe 406 as an exhausting unit and configured to be able to exhaust the processing liquid in the reserve tank 301 or the tank supply pipe 405. Also, the processing liquid may be returned to the processing liquid supply source 401 by providing an automatic valve 407 and a return pipe 408.

(Line Switching Unit)

The line switching unit 500 is provided between the liquid flow rate control unit 300 and the processing liquid supplying unit 400. A valve operation is performed to the line switching unit 500 when the step described later is performed. The step includes a step of supplying the processing liquid from the processing liquid supplying unit 400 to the reserve tank 301, a step of exhausting the processing liquid from the reserve tank 301 to the exhausting pipe 406, and a step of exhausting the processing liquid which stays in the tank supply pipe 405. The step of supplying the processing liquid is performed by opening a tank-side valve 501a and a supply-source-side valve 501b and closing an exhaust-side valve 501c. The step of exhausting the processing liquid is performed by opening the tank-side valve 501a and the exhaust-side valve 501c and closing the supply-source-side valve 501b. The step of exhausting the processing liquid in the pipe is performed by closing the tank-side valve 501a and opening the supply-source-side valve 501b and the exhaust-side valve 501c.

(Exhaust Unit)

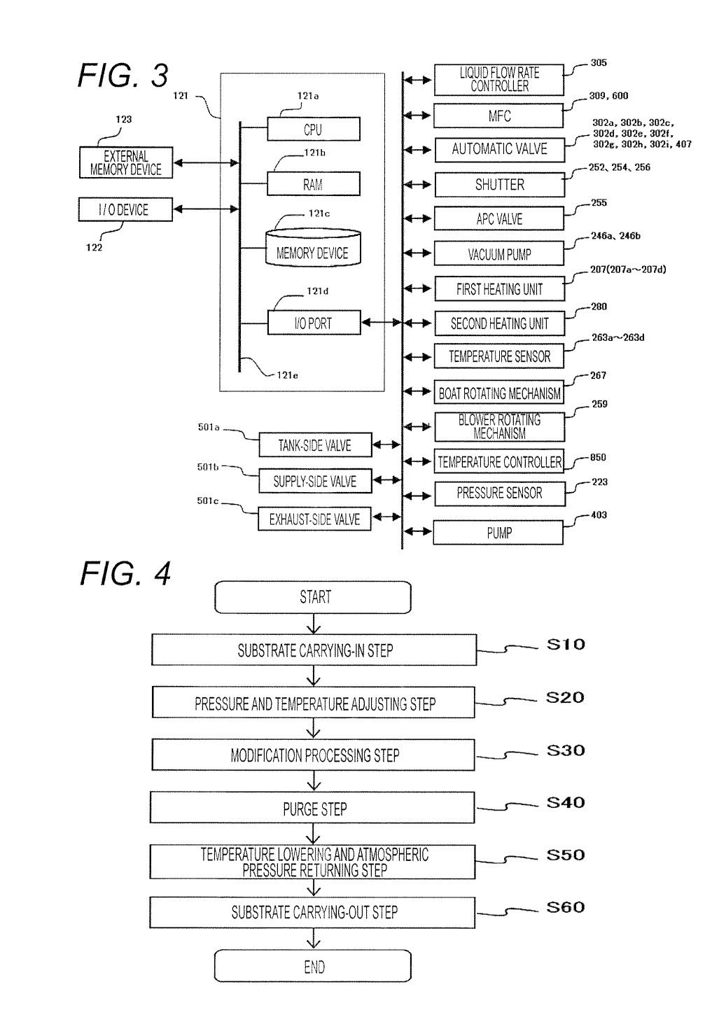

The lower part of the reaction tube 203 is connected to one end of a gas exhaust pipe 231 which exhausts the gas in the substrate processing chamber 201. Another end of the gas exhaust pipe 231 is connected to a vacuum pump 246a (exhausting device) via an auto pressure controller (APC) valve 255 as a pressure regulator. The gas in the substrate processing chamber 201 is exhausted by a negative pressure generated by the vacuum pump 246. The APC valve 255 is a switching valve which can exhaust and stop exhausting the gas in the substrate processing chamber 201 by opening/closing the valve. Also, the APC valve 255 is a pressure regulating valve which can adjust the pressure by adjusting the degree of valve opening. Also, a pressure sensor 223 as a pressure detector is provided on the upstream side of the APC valve 255. In this way, the exhaust unit is configured to perform vacuum-exhaust so that the pressure in the substrate processing chamber 201 becomes a predetermined pressure (vacuum degree). The substrate processing chamber 201 and the pressure sensor 223 are electrically connected to a pressure controller 284 (refer to FIG. 3) by the APC valve 255. The pressure controller 284 is configured to perform the control at a desired timing based on the pressure detected by the pressure sensor 223 so that the pressure in the substrate processing chamber 201 is changed to a desired pressure by the APC valve 255.

The exhaust unit includes the gas exhaust pipe 231, the APC valve 255, the pressure sensor 223, and the like. The vacuum pump 246 may be included in the exhaust unit.

In FIGS. 1 and 2, the processing liquid supplying nozzle 501 is provided at a position opposed to the gas exhaust pipe 231. However, they may be provided on the same side. Empty spaces in the substrate processing apparatus and in the semiconductor device factory where a plurality of substrate processing apparatuses is provided are small. Therefore, by providing the processing liquid supplying nozzle 501 and the gas exhaust pipe 231 on the same side in this way, it is easy to perform maintenance to a gas supplying pipe 233, the gas exhaust pipe 231, and a second heating unit (a liquefaction preventing heater) 280.

(Controlling Unit)

As illustrated in FIG. 3, the controller 121 which is a controlling unit is configured as a computer including a central processing unit (CPU) 121a, a random access memory (RAM) 121b, a memory device 121c, and an I/O port 121d. The RAM 121b, the memory device 121c, and the I/O port 121d are configured to be able to exchange data with the CPU 121a via an internal bus 121e. The controller 121 is connected to an I/O device 122 configured as a touch panel and the like.

The memory device 121c includes, for example, a flash memory and a hard disk drive (HDD). A control program for controlling an operation of the substrate processing apparatus and a program recipe in which a procedure and a condition of substrate processing described later are written are stored in the memory device 121c in a readable state. A process recipe is a combination of the procedures in the substrate processing step described later so as to obtain a predetermined result by performing the procedures by the controller 121, and the process recipe functions as a program. The program recipe and the control program are collectively referred to as a program below. When a word such as “program” is used herein, there are a case where the program recipe is included, a case where only the control program is included, and a case where both of them are included. Also, the RAM 121b is configured as a memory region (work area) where the program, the data, and the like read by the CPU 121a are temporarily held.

The I/O port 121d is connected to the LMFC 305, the MFCs 309 and 600, the pump 403, the automatic valves 302a, 302b, 302c, 302d, 302e, 302f, 302g, 302h, 302i, 601a, and 601b, shutters 252, 254, and 256, the APC valve 255, the first heating units 207 (207a to 207d), a second heating unit 280, a blower rotating mechanism 259, the first to fourth temperature sensors 263a to 263d, the boat rotating mechanism 267, the pressure sensor 223, the temperature controller 400, the pump 403, the tank-side valve 501a, the supply-source-side valve 501b, the exhaust-side valve 501c, and the like.

The CPU 121a reads and performs the control program from the memory device 121c and reads the process recipe from the memory device 121c according to an input of an operation command from the I/O device 122 and the like. The CPU 121a is configured to control the operations along the content of the read process recipe. The operations to be controlled include an operation for adjusting the flow rate of the processing liquid by the LMFC 305, an operation for adjusting the flow rate of the gas by the MFCs 309 and 600, an operation for opening/closing the automatic valves 302a, 302b, 302c, 302d, 302e, 302f, 302g, 302h, 302i, 601a, and 601b, an blocking operation by the shutters 252, 254, and 256, an operation for adjusting the opening/closing of the APC valve 255, an operation for adjusting the temperature of the first heating units 207 based on the first to fourth temperature sensors 263a to 263d, an operation for adjusting the temperature of the second heating unit 280, start/stop the vacuum pumps 246a and 246b, an operation for adjusting the rotation speed of the blower rotating mechanism 259, an operation for adjusting the rotation speed of the boat rotating mechanism 267, an operation for supplying the processing liquid by the pump 403, an operation for opening/closing the tank-side valve 501a, an operation for opening/closing the supply-source-side valve 501b, an operation for opening/closing the exhaust-side valve 501c, and the like.

The controller 121 is not limited to be configured as a dedicated computer and may be configured as a general purpose computer. For example, the controller 121 according to the present embodiment can be configured by preparing an external memory device (for example, a magnetic tape, a magnetic disk such as a flexible disk and a hard disk, an optical disk such as a CD and DVD, an optical magnetic disk such as a MO, a semiconductor memory such as a USB memory and a memory card) 123 in which the program has been stored and installing the program to the general purpose computer by using the external memory device 123. In addition, a method to supply the program to the computer is not limited to a case where the program is supplied via the external memory device 123. For example, the program may be supplied by using a communication unit such as Internet and a dedicated line without using the external memory device 123. The memory device 121c and the external memory device 123 are configured as the computer readable recording medium. These are collectively referred to as “recording medium” below. When a word such as “recording medium” is used herein, there are a case where only the memory device 121c is included, a case where only the external memory device 123 is included, and a case where both of them are included.

(2) Substrate Processing Step

Subsequently, a substrate processing step performed as one step of a step of manufacturing a semiconductor device according to the present embodiment will be described with reference to FIG. 4. The step is performed by the substrate processing apparatus. In the present embodiment, as an exemplary substrate processing step, a case will be described where vaporized gas which is generated by vaporizing hydrogen peroxide water is used as processing gas and a step of modifying (oxidizing) a silicone (Si)-containing film formed on the wafer 200 as the substrate to a silicone oxide film (modification processing step) is performed. In the following description, the operation of each unit included in the substrate processing apparatus is controlled by the controller 121 illustrated in FIGS. 1 and 3.

Here, an example will be described in which a substrate, which has pattern features that is a fine structure and to which polysilazane (SiH₂NH) is supplied at least to fill a recess part (groove) with it and in which the silicone (Si)-containing film is formed in the groove, is used as the wafer 200 and vaporized gas of the hydrogen peroxide water is used as the processing gas. The silicon-containing film includes silicon (Si), nitrogen (N), and hydrogen (H). In some cases, there is a possibility that carbon (C) and other impurities have been mixed. The substrate having the fine structure is a substrate having a structure with a high aspect ratio such as a groove (recessed part) which is deep in the vertical direction relative to the silicon substrate or a groove (recessed part) which has a width of about 10 to 50 nm and which is narrow in the horizontal direction.

The polysilazane is used instead of the SOG which has been traditionally used. The polysilazane is a material obtained, for example, by a catalytic reaction of dichlorosilane and trichlorosilane with ammonia. Polysilazane is used to form a thin film by coating polysilazane on the substrate by using a spin coater. The film thickness is adjusted according to the molecular weight and viscosity of polysilazane and the number of rotations of the coater. The silicone oxide film can be formed by supplying moisture to polysilazane.

(Substrate Carrying-In Step (S10))

The wafers 200 are charged on the boat 217 (wafer charge) with the number of the wafers 200 being previously specified. The boat 217 which has held the plurality of wafers 200 is lifted by the boat elevator and loaded in the reaction tube 203 (in the processing chamber 201) (boat load). In this state, the opening that is an opening part of the processing furnace 202 is sealed with the seal cap 219.

(Pressure and Temperature Adjusting Step (S20))

At least one of the vacuum pump 246a or vacuum pump 246b performs the vacuum-exhaust so that the pressure in the reaction tube 203 becomes a desired pressure (for example, 96000 to 102500 Pa). Specifically, the pressure is about 100000 Pa. At this time, the pressure in the reaction tube 203 is measured by the pressure sensor 223, and feedback control is performed to the opening of the APC valve 242 or the opening/closing of the valve 240 based on the measured pressure (pressure adjustment).

The first heating unit 207 heats the wafer 200 housed in the reaction tube 203 so that the temperature of the wafer 200 becomes a desired temperature (for example, room temperature to 300° C.). Preferably, the wafer 200 is heated to about 50° C. to 150° C., and more preferably, heated to about 50 to 100° C. At this time, the feedback control is performed to the power supplied to the first to fourth heater units 207a to 207d included in the first heating unit 207 based on the temperature information detected by the first to fourth temperature sensors 263a to 263d so that the wafer 200 in the reaction tube 203 has a desired temperature (temperature adjustment). At this time, all the set temperatures of the first to fourth heater units 207a to 207d may be controlled to be the same, and the temperature of the heater opposite to the position where the vaporizer has been placed may be high. Also, the temperature of the heater opposite to the position on the lower end side of the boat 217 apart from the vaporizer may be controlled to be high.

Also, while the wafer 200 is heated, the boat rotating mechanism 267 is operated, and the boat 217 starts to rotate. At this time, the controller 121 controls the rotation speed of the boat 217. The boat 217 is constantly rotated at least before a modification processing step (S30) described later is terminated.

Also, the temperature of the exhaust tube heater 224 is adjusted to be 100 to 300° C. by supplying the power to it.

(Modification Processing Step (S30))

When the temperature of the wafer 200 has reached the desired temperature by heating the wafer 200 and the rotation speed of the boat 217 has reached the desired rotation speed, hydrogen peroxide (H₂O₂) water as the processing liquid is supplied to the vaporizer 217d, and the hydrogen peroxide water is evaporated. Then, hydrogen peroxide gas as the vaporized gas is generated in the substrate processing chamber 201. Specifically, the pumped gas is supplied from the gas supplying pipe 301 into the reserve tank 301 by opening the automatic valves 302a, 302b, 302c, 302d, 302e, 302f, and 302g. For example, nitrogen gas (N₂) is used as the pumped gas. In addition, inert gas and rare gas such as He gas, Ne gas, and Ar gas may be used. When the pumped gas is supplied to the reserve tank 301, the hydrogen peroxide water in the reserve tank 301 is pushed out to the liquid pipe 310a and supplied to the LMFC 305 via the filter 304. After the flow rate of the hydrogen peroxide water is has adjusted to a predetermined flow rate by the LMFC 305, the hydrogen peroxide water is dripped to the vaporizer 217d via the processing liquid supplying nozzle 501. The vaporizer 217d is heated to be a predetermined temperature, and the hydrogen peroxide water supplied to the vaporizer 217d is evaporated. Then, the hydrogen peroxide gas is generated. The hydrogen peroxide concentration in the hydrogen peroxide gas can be controlled with high reproducibility by generating the hydrogen peroxide gas in the processing chamber 201 in this way. The hydrogen peroxide water is solution in which hydrogen peroxide (H₂O₂) and water (H₂O) are mixed. A boiling point of H₂O₂ is different from that of H₂O. Therefore, the H₂O₂ concentration of the liquid state may be different from that of the hydrogen peroxide gas after the liquid is evaporated by using a method of heating and evaporating the solution including the hydrogen peroxide water and a method of bubbling the solution. As in the present embodiment, when a method of dripping and evaporating the solution is used, a difference between the concentrations can be reduced.

The vaporized gas (processing gas) of the hydrogen peroxide water is supplied to the wafer 200, and the vaporized gas of the hydrogen peroxide water performs oxidizing reaction with the surface of the wafer 200. Accordingly, the silicon-containing film formed on the wafer 200 is modified to a SiO film.

While the hydrogen peroxide water is supplied to the reaction tube 203, the exhaust is performed from the vacuum pump 246b and a liquid collecting tank 247. That is, the APC valve 242 is closed and the valve 240 is opened so that the exhaust gas exhausted from the reaction tube 203 passes from the gas exhaust pipe 231 through a separator 244 via a second exhaust pipe 243. After the exhaust gas has been separated into liquid including hydrogen peroxide and gas which does not include hydrogen peroxide by the separator 244, the gas is exhausted from the vacuum pump 246b, and the liquid is collected to the liquid collecting tank 247.

When the hydrogen peroxide water is supplied to the reaction tube 203, the pressure may be applied to the reaction tube 203 by closing the valve 240 and the APC valve 255. Accordingly, hydrogen peroxide water atmosphere in the reaction tube 203 can be uniformed.

After a predetermined time has been elapsed, the automatic valve 302c is closed, and the supply of the hydrogen peroxide water to the reaction tube 203 is stopped.

Also, the processing gas is not limited to the vaporized gas of the hydrogen peroxide water. For example, gas may be used in which gas including hydrogen element (H) such as hydrogen (H₂) gas (hydrogen-containing gas) and gas including oxygen element (O) such as oxygen (O₂) gas (oxygen-containing gas) are heated and vaporized (H₂O). Also, water including ozone (O₃) may be supplied.

(Purge Step (S40))

After the modification processing step (S30) has been completed, the automatic valves 302c, 302b, 302j, 302a, 302e, 302f, and 302g are closed and the automatic valve 302i is opened so that the hydrogen peroxide water which remains in the processing liquid supplying nozzle 501 is exhausted from the drain pipe 310e. After the hydrogen peroxide water has been exhausted, the vacuum-exhaust is performed to the reaction tube 203 by closing the automatic valve 302d and opening the valve 255. Then, the hydrogen peroxide remaining in the reaction tube 203 is exhausted. At this time, the exhaust of the residual gas in the reaction tube 203 can be urged by supplying N₂ gas (inert gas) as purge gas from the inert gas supplying pipe 602 into the reaction tube 203.

(Temperature Lowering and Atmospheric Pressure Returning Step (S50))

After the purge step (S40) has been completed, while the pressure in the reaction tube 203 is returned to the atmospheric pressure by adjusting the valve 255 or the APC valve 246a, the temperature of the wafer 200 is decreased to a predetermined temperature (for example, about room temperature). Specifically, while the automatic valves 601a and 601b are kept open and N₂ gas which is the inert gas is supplied into the reaction tube 203, the valve 255 or the APC valve 246a is gradually closed, and the pressure in the reaction tube 203 is increased to the atmospheric pressure. The temperature of the wafer 200 is decreased by controlling the power supply to the first heating unit 207 and the second heating unit 280.

The shutter 252, 254, and 256 are opened in a state where a blower 257 is operated while the temperature of the wafer 200 is decreased, cooling gas is supplied from the cooling gas supplying pipe 249 into a space 260 between the reaction tube 203 and the heat insulation member 210 while a flow rate of the cooling gas is controlled by the mass flow controller 251, and the gas may be exhausted from the cooling gas exhaust pipe 253. In addition to N₂ gas, for example, rare gas such as He gas, Ne gas, and Ar gas and air can be used alone or can be used by mixing them as the cooling gas. Accordingly, the space 260 is rapidly cooled, and the reaction tube 203 and the first heating unit 207 provided in the space 260 can be cooled in a short time. Also, the temperature of the wafer 200 in the reaction tube 203 can be decreased in a short time.

In a state where the shutters 254 and 256 have been closed, N2 gas is supplied from the cooling gas supplying pipe 249 to the space 260. After the space 260 has been cooled by being filled with the cooling gas, the shutters 254 and 256 are opened in a state where the blower 257 has been operated. Then, the cooling gas in the space 260 may be exhausted from the cooling gas exhaust pipe 253.

Also, when the temperature of the wafer 200 is the temperature, which has no effect on apparatuses provided outside the processing chamber 201, for example, 100° C. in the modification processing step (S30), it is not necessary to decrease the temperature of the wafer.

(Substrate Carrying-Out Step (S60))

After that, the lower end of the reaction tube 203 is opened by descending the seal cap 219 by the boat elevator, and the processed wafer 200 is carried out from the lower end of the reaction tube 203 to the outside of the reaction tube 203 (processing chamber 201) (boat unload) in a state where the wafer 200 has been held by the boat 217. After that, the processed wafer 200 is discharged from the boat 217 (wafer discharge), and the substrate processing step according to the present embodiment is completed.

Here, the step of simply supplying the hydrogen peroxide gas to the silicon-containing film at a low temperature has been described. However, subsequently to the modification processing step S30, annealing may be performed to the wafer 200.

In the step of manufacturing the semiconductor device, the above-mentioned processes are repeated.

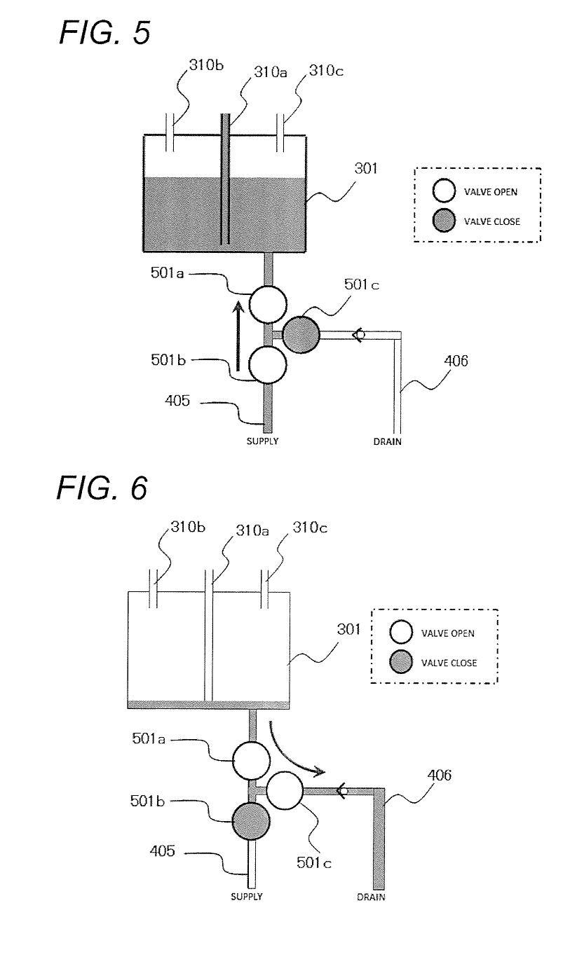

The amount of the hydrogen peroxide water stored in the reserve tank 301 is an amount in which substrate processing step can be performed at least once or more, and preferably, an amount in which the step can be performed for a plurality of time. In each substrate processing which is performed once or more, the hydrogen peroxide water is supplied from the processing liquid supplying unit 400 to the reserve tank 301. An interval between the substrate processing processes (between first substrate processing step to n+1th substrate processing step) may be longer. For example, the interval between the substrate processing processes gets longer due to the maintenance of the substrate processing apparatus. That is, time from when the hydrogen peroxide water stored in the reserve tank 301 is stored to the time when the hydrogen peroxide water is used to the substrate processing gets longer. The inventors have found a problem in that the decomposition of hydrogen peroxide water stored in the reserve tank 301 is advanced, the hydrogen peroxide water concentration is changed, and the reproducibility for each substrate processing step becomes worse due to the long storing time of the hydrogen peroxide water. The hydrogen peroxide water is decomposed into water (H₂O) and oxygen (O) with the elapse of time. Also, the inventors have found a problem in that the hydrogen peroxide concentration in the tank supply pipe 405 provided between the processing liquid supplying unit 400 and the reserve tank 301 is changed, the plurality of kinds of hydrogen peroxide water having different concentrations is supplied to the reserve tank 301, and then, the hydrogen peroxide concentration in the reserve tank 301 is changed. The inventors have found that these problems can be solved by performing the step of exhausting the processing liquid and the step of exhausting the processing liquid in the pipe before the processing liquid replenishing step to the reserve tank 301 described later is performed. These processes will be described below with reference to FIGS. 5 to 7.

(Processing Liquid Replenishing Step)

The automatic valve 302a and the automatic valve 302g are closed, and the supply of the pumped gas is stopped. Also, the supply of the hydrogen peroxide water is stopped, and the automatic valve 302h is opened. As illustrated in FIG. 5, the hydrogen peroxide water is supplied from the processing liquid supply source 401 to the reserve tank 301 by closing the exhaust-side valve 501c provided in the line switching unit 500, sequentially opening the supply-source-side valve 501b and the tank-side valve 501a, and driving the pump 403. The atmosphere in the reserve tank 301 is exhausted from the gas exhausting pipe 310c. The processing liquid replenishing step is performed at least when the pumped gas is not supplied. When a load of the controlling unit in the substrate processing step is considered, it is preferable that the processing liquid replenishing step be performed before the substrate carrying-in step S10 or after the substrate carrying-out step S60. Also, both or one of the step of exhausting the processing liquid and the step of exhausting the processing liquid in the pipe described later is performed before the processing liquid replenishing step.

(Step of Exhausting the Processing Liquid)

As illustrated in FIG. 6, the step is performed by closing the supply-source-side valve 501b provided in the line switching unit 500 arranged between the liquid flow rate control unit 300 and the processing liquid supplying unit 400, opening the tank-side valve 501a and the exhaust-side valve 501c, and sending and exhausting the hydrogen peroxide water stored in the reserve tank 301 to the exhausting pipe 406. The tank-side valve 501a is connected to a lower part of the reserve tank 301 so as to exhaust all the hydrogen peroxide water in the reserve tank 301. By exhausting the hydrogen peroxide water in the reserve tank 301 in this way, the hydrogen peroxide water with lowered concentration and hydrogen peroxide to be supplied can be prevented from being mixed. The method is not limited to this. The hydrogen peroxide water may be exhausted via the exhausting pipe 310e by supplying the pumped gas into the reserve tank 301. When the hydrogen peroxide water is exhausted via the exhausting pipe 310e, it is difficult to exhaust all the hydrogen peroxide water in the reserve tank 301. However, this step may be performed when the decrease in the concentration of the hydrogen peroxide is within an allowable range.

(Step of Exhausting the Processing Liquid in the Pipe)

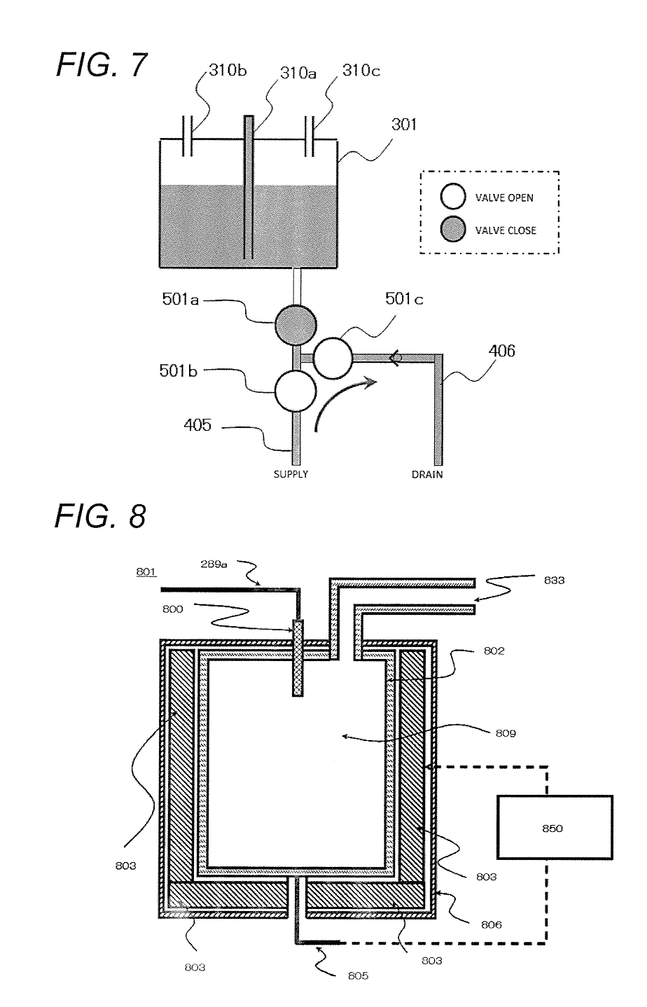

As illustrated in FIG. 7, the tank-side valve 501a provided in the line switching unit 500 is closed, the supply-source-side valve 501b and the exhaust-side valve 501c are opened, the pump 403 is driven, and the hydrogen peroxide water is exhausted from the processing liquid supply source 401 to the exhausting pipe 406 via the line switching unit 500. According to this, the hydrogen peroxide water with different concentration remained in the tank supply pipe 405 can be pushed out, and the hydrogen peroxide concentration in the tank supply pipe 405 can be returned to a predetermined concentration. Also, the hydrogen peroxide water may be returned from the return pipe 408 to the processing liquid supply source 401 by adjusting the automatic valve 407. Also, the hydrogen peroxide water may appropriately circulate by supplying it from the processing liquid supply source 401 to the supply-source-side valve 501b and the exhaust-side valve 501c and returning it to the processing liquid supply source 401 via the return pipe 408. By circulating the hydrogen peroxide water, it can be prevented that the hydrogen peroxide water is retained.

In the processing liquid replenishing process, the step of exhausting the processing liquid, and the step of exhausting the processing liquid in the pipe, when the tank-side valve 501a, the supply-source-side valve 501b, and the exhaust-side valve 501c are controlled by the controller, and an interlock is provided so as to prevent a state where the three valves are opened at the same time and a state where the three processes are performed together.

The embodiment has been specifically described above. However, the embodiment is not limited to the above-mentioned embodiment and can be variously changed without departing from the scope of the embodiment.

In the above description, a mode in which hydrogen peroxide gas is generated by using the hydrogen peroxide water (H₂O₂) has been described. However, the mode is not limited to this, and the gas supplied to the wafer 200 may include a state of a H₂O₂ molecular and a cluster state where several molecules are combined. Also, when gas is generated from liquid, the liquid may be divided into a H₂O₂ molecular and may be divided into the cluster state where several molecules are combined. Also, the state may be mist state where the some clusters are collected.

The step of manufacturing the semiconductor device which performs processing to the wafer 200 and that for burying an insulator in the fine groove have been described above. However, the invention according to the embodiment can be applied to a step other than that. For example, the present invention can be applied to a step of forming an interlayer insulating film of the semiconductor device substrate and a step of sealing the semiconductor device.

Also, the step of manufacturing the semiconductor device has been described above. However, the invention according to the embodiment can be applied to a step other than the step of manufacturing the semiconductor device. For example, the present invention can be applied to processing for sealing a substrate having a liquid crystal in a step of manufacturing a liquid crystal device and processing for performing water repellent coating to a glass substrate and a ceramic substrate used by various devices. In addition, the present invention can be applied to processing for performing water repellent coating to a mirror.

Also, in the above embodiment, an example has been described in which the hydrogen peroxide (H₂O₂) water is heated and evaporated and the gas is generated. The present invention is not limited to this. A method of changing the water (H₂O) and the hydrogen peroxide (H₂O₂) into mist by adding ultrasonic waves to them and a method of spraying the mist by using an atomizer may be used. Also, a method of evaporating the processing liquid by directly irradiating the processing liquid with laser and microwaves at a moment.

Also, in the above-mentioned embodiment, an example has been described in which the processing gas is generated in the processing chamber 201. However, the present invention is not limited to this. A vaporizer (hydrogen peroxide vapor generator 801) as illustrated in FIG. 8 may be provided outside the processing chamber 201. The hydrogen peroxide vapor generator 801 uses a dripping method of vaporizing the processing liquid by dripping the processing liquid to a heated member. The hydrogen peroxide vapor generator 801 includes a dripping nozzle 800 as a liquid supplying unit for supplying the hydrogen peroxide water, a vaporizing container 802 as a member to be heated, a vaporizing space 809 including the vaporizing container 802, a vaporizer heater 803 as a heating unit for heating the vaporizing container 802, an exhaust port 833 for exhausting the vaporized raw material liquid to a reaction chamber, a thermocouple 805 for measuring the temperature of the vaporizing container 802, a temperature controller 850 for controlling the temperature of the vaporizer heater 803 based on the temperature measured by the thermocouple 805, and a chemical liquid supply piping 807 for supplying the raw material liquid to the dripping nozzle 800. The temperature of the vaporizing container 802 is set to a temperature at which the dripped processing liquid reaches the vaporizing container and is vaporized at the same time, and the vaporizing container 802 is heated by the vaporizer heater 803. Also, a heat insulator 806 is provided which can improve heating efficiency of the vaporizing container 802 by the vaporizer heater 803 and can insulate the hydrogen peroxide vapor generator 801 from other units. The vaporizing container 802 is formed of quartz, silicon carbide, and the like to prevent the reaction with the raw material liquid. The temperature of the vaporizing container 802 is decreased by the temperature of the dripped raw material liquid and heat of vaporization. Therefore, it is effective to use silicon carbide with heat conductivity to prevent temperature drop.

<Preferable Form>

A preferable form will be appended below.

### APPENDIX 1

According to one aspect, there is provided a substrate processing apparatus including:

a processing chamber configured to supply processing gas generated by evaporating processing liquid to a substrate and performing processing to it;

a reserve tank configured to temporarily store the processing liquid and supply it to the processing chamber;

a line switching unit configured to be connected to the reserve tank;

a tank supply pipe configured to be connected to the line switching unit and supply the processing liquid to the reserve tank;

an exhausting unit configured to be connected to the line switching unit and exhaust the processing liquid in the reserve tank; and

a controlling unit configured to control the line switching unit.

### APPENDIX 2

The substrate processing apparatus according to Appendix 1, wherein

preferably, the controlling unit controls the line switching unit to perform both or one of a step of exhausting the processing liquid for exhausting the processing liquid from the reserve tank to the exhausting unit and a step of exhausting the processing liquid in the pipe for exhausting the processing liquid from the tank supply pipe to the exhausting unit before and/or after a processing liquid replenishing step of supplying the processing liquid from the tank supply pipe to the reserve tank.

### APPENDIX 3

The substrate processing apparatus according to Appendix 1 or 2, wherein

preferably, the processing liquid includes hydrogen peroxide.

### APPENDIX 4

The substrate processing apparatus according to any one of Appendices 1 to 3, wherein

preferably, the controlling unit controls each unit to perform the processing liquid replenishing step every time when a substrate processing step of processing the substrate is performed for a predetermined number of times.

### APPENDIX 5

The substrate processing apparatus according to any one of Appendices 1 to 4, wherein

preferably, the controlling unit controls each unit to perform the step of exhausting the processing liquid and the step of exhausting the processing liquid in the pipe after maintenance of the substrate processing apparatus.

### APPENDIX 6

The substrate processing apparatus according to any one of Appendices 1 to 5, wherein

preferably, the controlling unit controls each unit to perform the step of exhausting the processing liquid in the pipe before or after the step of exhausting the processing liquid.

### APPENDIX 7

According to another aspect, there is provided a substrate processing apparatus including:

a processing chamber configured to house a substrate;

a vaporizer configured to vaporize processing liquid and supply processing gas into the processing chamber;

a reserve tank configured to store the processing liquid;

a flow rate control unit configured to control a flow rate of the processing liquid from the reserve tank to the vaporizer;

a line switching unit configured to be connected to the reserve tank;

a tank supply pipe configured to be connected to the line switching unit and supply the processing liquid to the reserve tank;

an exhausting unit configured to be connected to the line switching unit and exhaust the processing liquid in the reserve tank; and

a controlling unit configured to control the line switching unit to perform one or both of a step of exhausting the processing liquid for exhausting the processing liquid from the reserve tank to the exhausting unit and a step of exhausting the processing liquid in the pipe for supplying the processing liquid from the tank supply pipe to the exhausting unit before and/or after a processing liquid replenishing step of supplying the processing liquid from the processing liquid supplying pipe to the reserve tank.

### APPENDIX 8

The substrate processing apparatus according to Appendix 7, wherein

preferably, the controlling unit controls the flow rate control unit so that the vaporizer drips the processing liquid to a heated vaporizing unit and vaporization is performed.

### APPENDIX 9

According to still another aspect, there is provided a method of manufacturing a semiconductor device including:

a substrate processing step of supplying evaporated processing liquid to a substrate,

a processing liquid replenishing step of supplying the processing liquid from the tank supply pipe to the reserve tank, and

a step of performing one or both of a step of exhausting the processing liquid in the reserve tank from an exhausting unit and a step of exhausting the processing liquid from the tank supply pipe to the exhausting unit before and/or after the processing liquid replenishing step.

### APPENDIX 10

The method of manufacturing a semiconductor device, according to Appendix 9, wherein

preferably, the processing liquid replenishing step is performed after the substrate processing step has been performed for a predetermined number of times.

### APPENDIX 11

The method of manufacturing a semiconductor device, according to Appendix 9 or 10, wherein preferably, the step of exhausting the processing liquid and the step of exhausting the processing liquid in the pipe are performed after maintenance.

### APPENDIX 12

The method of manufacturing a semiconductor device, according to any one of Appendices 9 to 11, wherein

preferably, the step of exhausting the processing liquid in the pipe is performed before/after the step of exhausting the processing liquid.

### APPENDIX 13

According to yet another aspect, there is provided a method of manufacturing a semiconductor device including:

a step of housing a substrate in a processing chamber;

a step of vaporizing processing liquid and supplying processing gas into the processing chamber;

a step of storing the processing liquid in a reserve tank;

a step of controlling a flow rate of the processing liquid from the reserve tank to the vaporizer;

a processing liquid replenishing step of supplying the processing liquid from a tank supply pipe to the reserve tank; and

a step of performing one or both of a step of exhausting the processing liquid in the reserve tank from an exhausting unit and a step of exhausting the processing liquid from the tank supply pipe to the exhausting unit before and/or after the processing liquid replenishing step.

### APPENDIX 14

The method of manufacturing a semiconductor device, according to Appendix 13, further including:

a step of preferably controlling a flow rate of the processing liquid so that the vaporizer drips the processing liquid to a heated vaporizing unit and vaporization is performed.

### APPENDIX 15

According to still yet another aspect, there is provided a non-transitory computer-readable recording medium including a program which makes a computer perform a substrate processing procedure of supplying evaporated processing liquid to a substrate, a processing liquid supplying procedure of supplying the processing liquid from a tank supply pipe to a reserve tank, and a procedure of performing one or both of a procedure of exhausting the processing liquid in the reserve tank from an exhausting unit and a procedure of exhausting the processing liquid from the tank supply pipe to the exhausting unit before and/or after the processing liquid supplying procedure.

### APPENDIX 16

According to another aspect, there is provided a non-transitory computer-readable recording medium in which a program has been recorded, and

the program makes a computer perform a substrate processing procedure of supplying evaporated processing liquid to a substrate, a processing liquid supplying procedure of supplying the processing liquid from a tank supply pipe to a reserve tank, and a procedure of performing one or both of a procedure of exhausting the processing liquid in the reserve tank from an exhausting unit and a procedure of exhausting the processing liquid from the tank supply pipe to the exhausting unit before and/or after the processing liquid supplying procedure.

### REFERENCE SIGNS LIST

200 wafer (substrate)
201 substrate processing apparatus
203 reaction tube
207 first heating unit
217 boat
231 gas exhaust pipe
501 processing liquid supplying nozzle
502 supply hole
300 liquid flow rate control unit
301 reserve tank
400 processing liquid supplying unit
500 line switching unit
121 controller

1. A substrate processing apparatus comprising:
a processing chamber configured to house a substrate;
a vaporizer configured to vaporize processing liquid and supply processing gas into the processing chamber;
a reserve tank configured to store the processing liquid;
a flow rate control unit configured to control a flow rate of the processing liquid from the reserve tank to the vaporizer;
a line switching unit configured to be connected to the reserve tank;
a tank supply pipe configured to be connected to the line switching unit and supply the processing liquid to the reserve tank;
an exhausting unit configured to be connected to the line switching unit and exhaust the processing liquid in the reserve tank; and
a controlling unit configured to control the line switching unit to exhaust the processing liquid from the reserve tank to the exhausting unit, and to exhaust the processing liquid from the tank supply pipe to the exhausting unit before and/or after a processing liquid replenishing of supplying the processing liquid from the tank supply pipe to the reserve tank.

2. The substrate processing apparatus according to claim 1, wherein
the controlling unit controls the flow rate control unit so that the processing liquid is supplied to a heated vaporizing unit and vaporization is performed in the vaporizer.

3. The substrate processing apparatus according to claim 1, wherein
the processing liquid includes hydrogen peroxide.

4. The substrate processing apparatus according to claim 1, wherein
the controlling unit controls the line switching unit to exhaust the processing liquid in the pipe before or after exhausting the processing liquid.

5. The substrate processing apparatus according to claim 1, wherein
the controlling unit controls the line switching unit to perform the processing liquid replenishing every time processing the substrate is performed for a predetermined number of times.

6. The substrate processing apparatus according to claim 1, wherein
the controlling unit controls the line switching unit to exhaust the processing liquid in the tank supply pipe after maintenance of the substrate processing apparatus.

7. A method of manufacturing a semiconductor device comprising:
(a) housing a substrate in a processing chamber;
(b) storing processing liquid in a reserve tank;
(c) supplying the processing liquid from the reserve tank to a vaporizer;
(d) vaporizing the processing liquid and supplying processing gas into the processing chamber;
(e) supplying the processing liquid from a tank supply pipe to the reserve tank; and
(f) performing a step of exhausting the processing liquid in the reserve tank from an exhausting unit and a step of exhausting the processing liquid from the tank supply pipe to the exhausting unit before and/or after the act of (e).

8. The method of manufacturing a semiconductor device, according to claim 7, further comprising:
controlling a flow rate of the processing liquid supplied to the vaporizer so that the processing liquid is supplied to a heated vaporizing unit and vaporization is performed in the vaporizer.

9. The method of manufacturing a semiconductor device, according to claim 7, wherein
exhausting the processing liquid from the tank supply pipe to the exhausting unit is performed before or after exhausting the processing liquid in the reserve tank from an exhausting unit.

10. The method of manufacturing a semiconductor device, according to claim 7, wherein
the act of (e) is performed after the act of (c) and (d) has been performed for a predetermined number of times.

11. The method of manufacturing a semiconductor device, according to claim 7, wherein
exhausting the processing liquid in the reserve tank from an exhausting unit and exhausting the processing liquid from the tank supply pipe to the exhausting unit are performed after maintenance.

12. A non-transitory computer-readable recording medium storing a program for making a computer perform:
a procedure of housing a substrate in a processing chamber,
a procedure of storing processing liquid in a reserve tank,
a procedure of supplying the processing liquid from the reserve tank to the vaporizer,
a procedure of vaporizing the processing liquid and supplying processing gas in the processing chamber,
a procedure of supplying the processing liquid from the tank supply pipe to the reserve tank, and
a procedure of exhausting the processing liquid in the reserve tank from an exhausting unit and a procedure of exhausting the processing liquid from the tank supply pipe to the exhausting unit before and/or after the procedure of supplying the processing liquid from the tank supply pipe to the reserve tank.

13. The non-transitory computer-readable recording medium according to claim 12, further comprising:
a procedure of controlling a flow rate of the processing liquid supplied to the vaporizer so that the processing liquid is supplied to a heated vaporizing unit and vaporization is performed in the vaporizer.

14. The non-transitory computer-readable recording medium according to claim 12, wherein
the procedure of exhausting the processing liquid from the tank supply pipe to the exhausting unit is performed before or after the procedure of exhausting the processing liquid in the reserve tank from an exhausting unit.

15. The non-transitory computer-readable recording medium according to claim 12, wherein
a procedure of supplying the processing liquid from the reserve tank to the vaporizer is performed after the procedure of supplying the processing liquid from the reserve tank to the vaporizer and the procedure of vaporizing the processing liquid has been performed for a predetermined number of times.

16. The non-transitory computer-readable recording medium according to claim 12, wherein
the procedure of exhausting the processing liquid in the reserve tank from an exhausting unit and the procedure of exhausting the processing liquid from the tank supply pipe to the exhausting unit are performed after a maintenance procedure.

17. The non-transitory computer-readable recording medium according to claim 12, wherein
the procedure of exhausting the processing liquid in the reserve tank from an exhausting unit and the procedure of exhausting the processing liquid from the tank supply pipe to the exhausting unit are performed before the procedure of supplying the processing liquid from the tank supply pipe to the reserve tank.
